(19) United States
(12) Patent Application Publication
(10) Pub. No.: US 2013/0177823 A1
(43) Pub. Date: Jul. 11, 2013

(54) Systems, Devices, and/or Methods for Power Generation from Water

(71) Applicants: Khe C. Nguyen, Ho Chi Minh City (VN); Hieu Dinh, San Jose, CA (US)

(72) Inventors: Khe C. Nguyen, Ho Chi Minh City (VN); Hieu Dinh, San Jose, CA (US)

(73) Assignee: K TUBE TECHNOLOGY LLC, San Jose, CA (US)

(21) Appl. No.: 13/433,241

(22) Filed: Mar. 28, 2012

Related U.S. Application Data
(60) Provisional application No. 61/583,234, filed on Jan. 5, 2012.

(51) Int. Cl. H01M 8/06; H05K 13/00; F02B 43/10; H01M 8/00

(52) U.S. Cl. 429/411; 429/535; 29/592.1; 123/3

(57) ABSTRACT

Certain exemplary embodiments provide a system adapted to generate hydrogen, which can comprise a water supply source, hydrogen producing agent, hydrogen collector, hydrogen purifier, a hydrogen outlet, a fuel cell, a storage device for electricity, and an inverter. The inverter can be adapted to convert direct current (“DC”) electrical energy into alternating current (“AC”) electrical energy.

### CROSS-REFERENCES TO RELATED APPLICATIONS

This application claims priority to, and incorporates by reference herein in its entirety, pending U.S. Patent Application Ser. No. 61/583,234 (Attorney Docket No. 1200-005), filed 5 Jan. 2012.

This application is related to, and incorporates by reference herein in its entirety, pending U.S. patent application Ser. No. 13/290,108 (Attorney Docket No. 1200-003), filed 17 Nov. 2011.

### BRIEF DESCRIPTION OF THE DRAWINGS

A wide variety of potential embodiments will be more readily understood through the following detailed description of certain exemplary embodiments, with reference to the accompanying exemplary drawings in which:

FIG. 1 is a block diagram of an exemplary embodiment of a power generator 1000;

FIG. 2 is a block diagram of an exemplary embodiment of a fuel cell system 2000;

FIG. 3 is a flowchart of an exemplary embodiment of a method 3000;

FIG. 4 is a block diagram of an exemplary embodiment of a power generator 4000; and

FIG. 5 is a block diagram of an exemplary embodiment of a system 5000.

### DETAILED DESCRIPTION

Certain exemplary embodiments provide a system adapted to generate hydrogen, which can comprise a water supply source, hydrogen producing agent, hydrogen collector, hydrogen cooling down tank, hydrogen purifier, a hydrogen outlet, a fuel cell, a storage device for electricity, and an inverter. The inverter can be adapted to convert direct current (“DC”) electrical energy into alternating current (“AC”) electrical energy. The water supply source can supply any kind of water including tap water, sea water, urinated water, waste water, distilled water, soft drink (e.g., soft drinks such as a cola, fruit flavored drink, etc.), juice, water mix with water soluble solvents such as methanol, ethanol, propanol, isopropanol, and/or butanol, etc. The water can be supplied with any phase, such as water vapor, liquid water, and/or ice at a predetermined supply rate. In certain exemplary embodiments, the predetermined supply rate can be, on a liquid water flow basis, between approximately 0.001 milliliters (“ml”) per minute (“min”) and approximately 10,000.0 ml/min.

Hydrogen can be produced from water molecules using a technique such as electrolysis, pulsed electrolysis, and/or photo-induced hydrolysis, etc. In certain exemplary embodiments, reduction reaction can utilize a single chemical or a combination of a plurality of specific chemicals that are adapted to react with water molecules to generate hydrogen in an acceptable period of time, etc. In certain exemplary embodiments, a specific reduction reaction using a specific chemical combination can produce hydrogen gas. For example, hydrogen gas can be generated in a very short reaction time, such as less than approximately one second after being contacted with water molecule. The amount of generated hydrogen gas can be sufficient to provide at least 1000 amperes-hour when the hydrogen gas passes through an effective fuel cell system. In certain exemplary embodiments, the specific reduction reaction using specific chemical combination can produce hydrogen gas at a relatively low cost comparable with energy produced from the combustion of fossil and/or petroleum fuel sources.

The hydrogen producing combination can comprise electron donating molecules. The electron donating molecules can have certain kinds of effects such as providing an environment having a pH greater than approximately 7. The hydrogen producing combination can comprise electron donating molecules and/or elements in the I, II (alkaline metals) and III-V group of the periodic table.

The hydrogen producing combination can comprise hydrides such as ionic hydrides (which have significant ionic bonding character), covalent hydrides (which include the hydrocarbons and many other compounds which covalently bond to hydrogen atoms), interstitial hydrides (which may be described as having metallic bonding), transition metal hydride complexes, and/or deuterides, etc. Some examples of hydrides are nickel hydride (“NiH”), palladium hydride, lithium aluminum hydride, sodium borohydride, sodium hydride, diborane, ammonia, and/or hydrogen sulfide, etc.

The hydrogen producing combination can comprise one or more than one additives, which can comprise at least one of an organic acid, silica, liquid glass, and/or glass product generated via the reaction of alkaline and/or electron donating molecules with glass. The hydrogen producing combination can comprise reduction agents such as NaBH₄, AlCl₃/NaBH₄, LiAlH₄, sodium silica gel, and/or sodium silicides such as NaSi, Na₂Si, and/or Na₄Si₄, etc. The hydrogen producing combination can comprise one or more of these above mentioned chemicals in a suitable amount producing hydrogen fast and for a sufficiently long period of time.

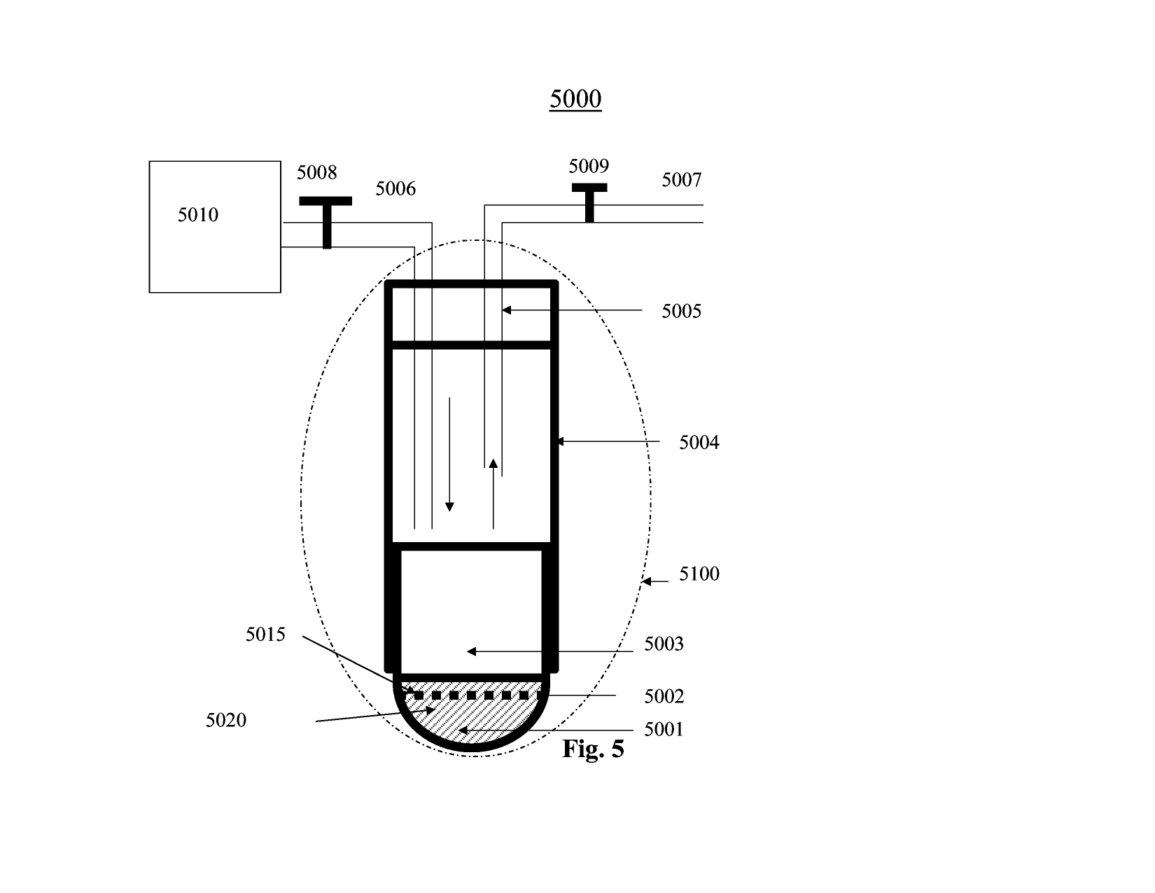

In certain exemplary embodiments the hydrogen producing combination can be stored. For example, the hydrogen producing combination can be stored in a nano container such as a single walled carbon nano tube (“SWNT”), double walled carbon nano tube (DWNT), multi-walled carbon nano tube (MWNT), Solid Phase synthesized carbon nano tube (SPNT), or in a micro container. In embodiments that utilize a micro container, the micro container can have a size ranging from several hundred microns to a few millimeters—such as a microcapsule or molecular sieve. The hydrogen producing combination can be stored in such a micro or nano container in a substantially solid form that can be delivered to contact and react with water molecules to form hydrogen. The first container can be stored in a second container that is relatively porous to liquid water and substantially completely enclosed, which can produce hydrogen when the lid is connected to water source (see, e.g., FIG. 5). This substantially enclosed container is a hydrogen producing unit which can supply hydrogen to fuel cell, and completely. Such units can be provided to a customer who can couple the container to a water source and a fuel cell. The substantially enclosed container can be replaceable after the hydrogen producing combination is spent. The substantially enclosed container has certain similarities to a gas supplying unit in a mini gas stove, which is adapted for use in cooking. Overall, a hydrogen generation subsystem can comprise a replaceable cartridge which comprises of H₂ producing combination, space for receiving water. The replaceable cartridge comprises of outlet connected to water source and outlet for H₂. Whenever, the H₂ producing combination is used off, the new cartridge will be used and the old cartridge can be recycled.

FIG. 5 is a block diagram of an exemplary embodiment of a system 5000, which can comprise a replaceable cartridge 5100 adapted for use in a hydrogen generation subsystem. Replaceable cartridge 5100 can comprise and/or be operatively coupled to a water supply source 5010. System 5000 can comprise a valve 5008 adapted to control the water supply to replaceable cartridge 5100. System 5000 can comprise a water supply inlet 5006, a valve 5009 adapted to control hydrogen gas flow, a produced hydrogen outlet 5007, a lid 5005, a container 5004, a water level controlling container 5003, a net open to hydrogen producing combination 5002, a hydrogen producing combination encapsulating container 5015, and/or a hydrogen producing combination container 5001, etc. Hydrogen producing combination encapsulating container 5015 can be a micro container in which hydrogen producing combination 5020 is microencapsulated. Hydrogen producing combination encapsulating container 5015 can be a nano container in which hydrogen producing combination 5020 is nanoencapsulated. Hydrogen producing combination container 5001 can be considered as a secondary container for hydrogen producing combination 5020. Replaceable cartridge 5100 can be a substantially closed box. Replaceable cartridge 5100 can comprise a hydrogen producing combination 5020. Hydrogen producing combination 5020 can comprise one or more of a plurality of chemicals, periodic table first column metals, periodic table III-V group elements, alkaline materials, and/or reduction molecules and/or reduction combination, etc.

Replaceable cartridge 5000 can be a component for a hydrogen producing and supplying subsystem adapted to generate power from water. The cartridge can be inserted into a power generator at the hydrogen outlet and operatively coupled to water source. When the water is supplied from water source, hydrogen is generated and supplied to the fuel cell subsystem of the power generator. When the hydrogen producing combination is spent and/or hydrogen is no longer supplied, the cartridge can be replaced by a new one and a user doesn't need to contact with the chemicals in the hydrogen producing combination. The hydrogen generation subsystem can be adapted to generate hydrogen used by a hydrogen fuel cell subsystem.

In certain exemplary embodiments, replaceable cartridge 5000 can comprise one or more of plastic, glass, ceramic, metal, wood, and/or a composite jar having suitable thickness to sustain effects of a gas explosion without being destroyed.

The hydrogen producing combination can be microencapsulated in a polymer adapted to prevent unnecessary contact between water molecules and reacting molecules. In certain exemplary embodiments, the hydrogen producing combination can be stored in a cartridge, which can be adapted to be nondestructively replaced in the system. In certain exemplary embodiments, the replaceable cartridge can be a filtering tea bag and/or a framing net close box.

A hydrogen generation subsystem can be adapted for use as a source of hydrogen for a hydrogen fuel cell. The hydrogen fuel cell can comprise a hydrogen transport pathway, oxygen transport pathway, air transport pathway, the PEM (proton exchange membrane) set up. The PEM set up comprises a PEM intercalated between catalyst layers deposited on a porous conductive substrate. The PEM can comprise alkyl sulfonate having general chemical structure:

R—SO₂—O—R′ (1)

In which R, R′ are alkyl, cyclo alkyl, and/or non-aromatic molecules. Examples of alkyl sulfonates comprise:
N-1-butane sulfonic acid sodium salt CH₃(CH₂)₃SO₃Na (CAS#2386-54-1);
N-1-pentane sulfonic acid sodium salt monohydrate CH₃(CH₂)₄SO₃Na.H₂O (CAS#22767-49-3);
Ethanesulfonic acid, sodium salt (CAS number 308103-56-2, Aldrich cat number 35, 910-6);
Sodium 1-butanesulfonate (CAS number 2386-54-1); and/or
Sodium 1-decanesulfonate (CAS number 13419-61-9).

Alkyl sulfonates can be used alone or embedded in a polymer to form a membrane.

The PEM can comprise a carbon-based substance, which can comprise at least one of sulfonated aromatic molecules, nano carbon materials, carbon black, carbon nano tube, carbon nano horn, carbon nano rod, carbon nano wire, graphite, graphene, graphene oxide, and/or graphene hybrid composite, etc. The carbon-based substance can be encapsulated in a polymer forming a membrane in a ratio such that substantially no effective electron transport occurs. The weight ratio of carbon material in the polymer (carbon/polymer weight ratio) can vary between approximately 0.0001 and approximately 10 depending upon the chemical structure of the polymer. Alkyl sulfonates can be used alone or can be embedded in a polymer matrix. In certain exemplary embodiments, the PEM can comprise one or more polymers having proton transport functionality such as sulfonated Teflon (Nafion—Teflon and Nafion are registered trademarks of E.I. DuPont De Nemours and Company of Delaware), sulfonated poly sulfon, sulfonated poly carbonate, sulfonated poly imidazole, sulfonated poly benzimidazole. In certain exemplary embodiments, the PEM can comprise sulfonated molecule(s) itself or sulfonated molecule(s) embedded in a polymer matrix. In certain exemplary embodiments, the PEM can comprise silicon (“Si”) derivatives. In certain exemplary embodiments, the Si derivatives can comprise silanol, —SiOH, —SiH, —SiO and/or silane coupling agents, etc.

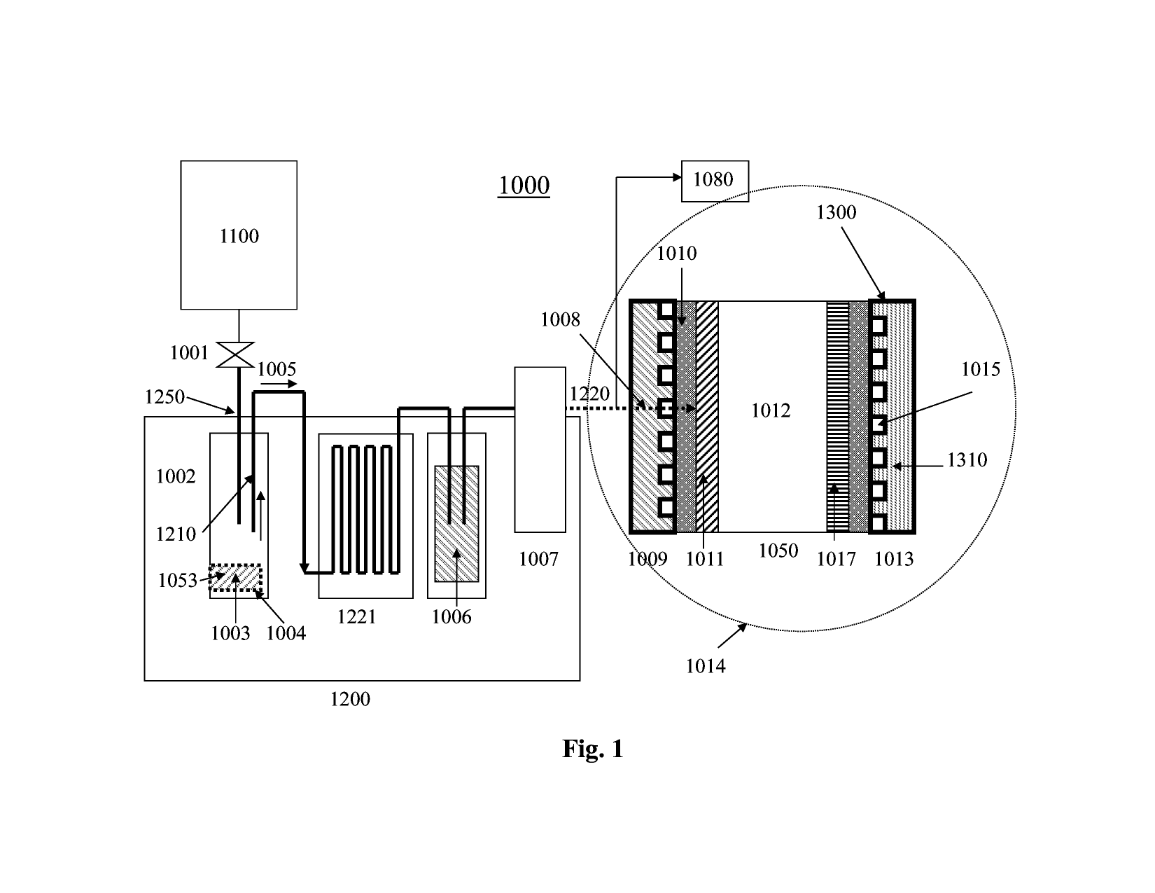

FIG. 1 is a block diagram of an exemplary embodiment of a power generator 1000, which can generate power from water. Power generator 1000 can comprise a hydrogen generation system 1200 and a system 1014 adapted to convert hydrogen into electricity (or hydrogen fuel cell system). Hydrogen generation system 1200 comprises water supply tank 1100, valve 1001, hydrogen producing combination container 1002, hydrogen producing combination 1003, hydrogen producing combination replaceable cartridge 1004, hydrogen collector 1210, and hydrogen cooling down system 1221, hydrogen gas 1005, hydrogen purifier 1006, hydrogen storage device 1007, and hydrogen outlet 1220. Hydrogen fuel cell system 1014 comprises relatively pure hydrogen gas 1008, hydrogen pathway 1009, conductive coating 1300, conductive or non-conductive frame 1310, porous conductive substrate 1010, catalyst 1011 and 1017, PEM 1012, oxygen/air pathway 1013, fuel cell 1050, and/or hydrogen internal combustion engine 1080, oxygen and/or air 1015.

Power generator 1000 can be adapted to produce electricity from water. Power generator 1000 can be adapted to produce hydrogen from water via hydrogen generation system 1200 into electrical energy. Hydrogen burning engine can be a hydrogen fuel cell system 1014, a hydrogen internal combustion engine 1080, or a combination of hydrogen fuel cell system 1014 and hydrogen internal combustion engine 1080.

Hydrogen generation system 1200 can adapted to receive water molecules from a water supply source such as water supply tank 1100. Flow from water supply tank 1100 can be controlled via valve 1001. Hydrogen producing combination 1003 can be adapted to generate hydrogen used by hydrogen fuel cell system 1014 and/or hydrogen internal combustion engine 1080. Hydrogen producing combination 1003 can comprise one or more electron donating molecules, which can comprise reduction molecules, metal, and/or a catalyst, etc. Hydrogen producing combination 1003 can be comprised by replaceable cartridge 1004. Replaceable cartridge 1004 can comprise a porous media 1053 adapted for contacting water molecules with hydrogen producing combination 1003.

Hydrogen fuel cell system 1014 can comprise a hydrogen fuel cell 1050. Hydrogen fuel cell 1050 can comprise hydrogen pathway 1009 and air/oxygen transport pathway 1013 and PEM 1012 intercalated between anode catalyst layers 1011 and cathode catalyst layer 1017 deposited on a porous conductive substrate 1010. PEM 1012 can comprise sulfonated nano carbon materials encapsulated in a first polymer forming a membrane, sulfonated polymers, and/or sulfonated compound embedded in a polymer matrix, etc. Hydrogen pathway 1009 and/or air/oxygen transport pathway 1013 can comprise conductive frame 1310, which can comprise at least one of a metal, metal alloy, graphite, graphene, graphene oxide, graphene nano platelets, hybrid graphene composite, carbon/metal alloy, carbon nano tube, carbon nano horn, carbon nano wire, and/or carbon nano rod, etc. Hydrogen pathway 1009 and/or air/oxygen transport pathway 1013 can be defined by a solid conductive frame and/or solid insulating frame covered with conductive coating by electroplating technique, vacuum sublimation technique, sputtering technique, and/or E beam, etc. If a plastic material is used to make frame 1310, frame 1310 can be coated with a solid state material having at least one of a first zero band gap material, an electrical conductive material, and/or a semiconducting material, etc. The first zero band gap material can comprise at least one of a metal, metal alloy, graphite, graphene, graphene oxide, graphene nano platelets, hybrid graphene composite, tubular nano carbon including carbon nano tube, carbon nano wire, carbon nano rod, carbon nano horn, carbon black, and/or semiconducting materials, etc. Semiconducting materials can comprise silicon nano wire, ZnO nano rod, ZnO nano wire, TiO2 nano rod, TiO2 nano wire, and/or oxides such as In2O3, SnO2, etc.

Hydrogen gas pathway 1009 and/or oxygen/air pathway 1013 can comprise a conductive frame. In certain exemplary embodiments, the conductive frame can comprise metal, graphite, graphene, graphene oxide, graphene nano platelets and/or a hybrid graphene composite. The hybrid graphene composite can be produced according to a method disclosed in related U.S. patent application Ser. No. 13/290,108. In certain exemplary embodiments, the framework can comprise a plastic frame in contact with a conductive mesh and/or a plastic frame covered with a conductive thin film, a metal thin film prepared by electroplating technique, by vacuum evaporation technique, sputtering technique, and/or E beam technique, etc. The conductive thin film or metal thin film can comprise a single element or an alloy of more than one element.

System 1000 can be utilized to generate electrical power from water. System 1000 can be used as a household power plant. In certain exemplary embodiments, hydrogen fuel cell system 1014 can be used to provide energy for portable devices, street lighting tool, a household, bicycle, motorcycle, automobile, power plant, airplane, space shuttle, and/or flying car, etc. In certain exemplary embodiments, system 1000 can be used as a part of a large scale power plant adapted to supply electrical energy to an electrical power distribution grid.

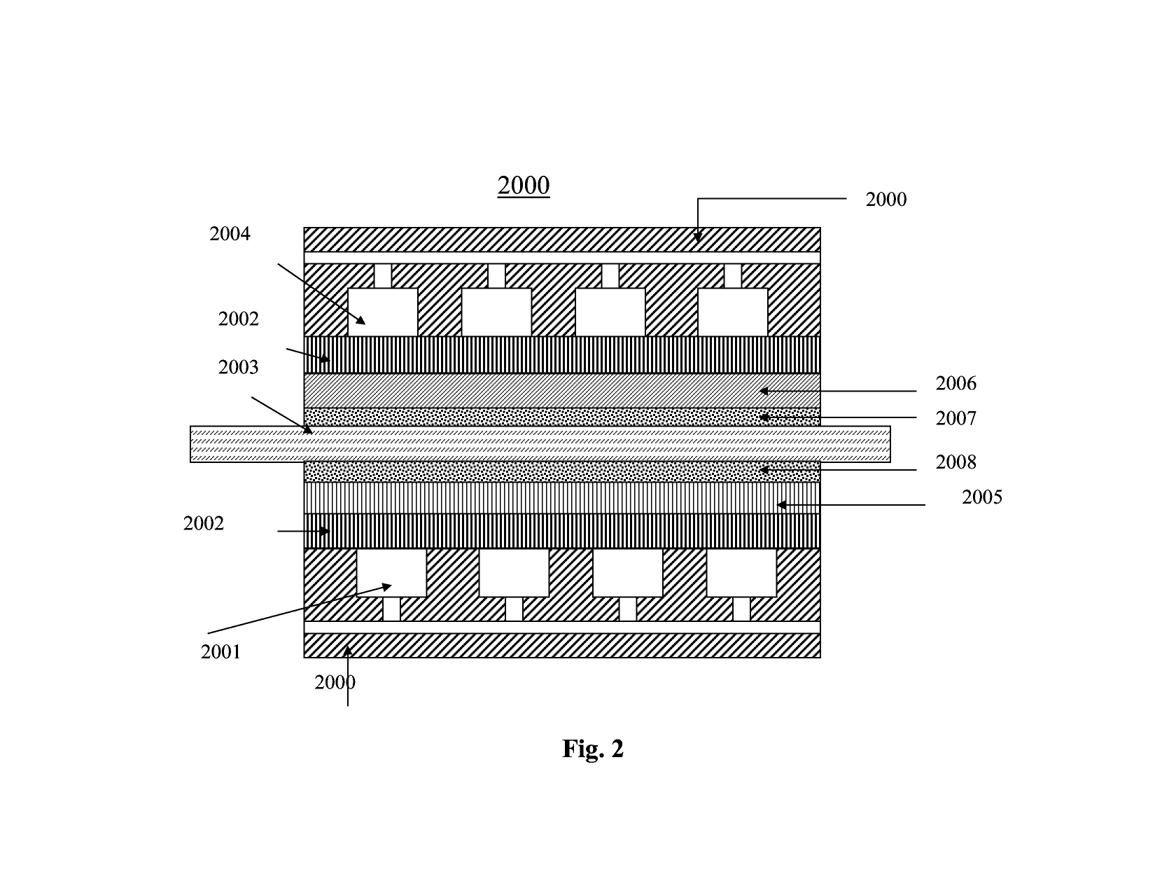

FIG. 2 is a block diagram of an exemplary embodiment of a system 2000, which can comprise a conductive frame 2000 and/or insulating frame covered with conductive coating, oxygen and/or air gap 2001, two porous conductive substrate for gas diffusion 2002, proton exchange membrane (PEM) 2003, hydrogen gap 2004, anode catalyst layer 2005, cathode catalyst layer 2006, and primer 2008 and 2007.

In certain exemplary embodiments, conductive frame 2000 can comprise an electrical porous conductive substrate in conjunction with a plastic frame. The plastic film can be covered by thin film of metal prepared by vacuum sublimation, electroplating, sputtering, and/or E beam, etc. In certain exemplary embodiments, conductive frame 2000 can comprise a plastic frame covered by thin film of metal prepared by electroplating in conjunction with the electrical porous conductive substrate. In certain exemplary embodiments, conductive frame 2000 can comprise fibril cotton packed on the top of a porous conductive substrate.

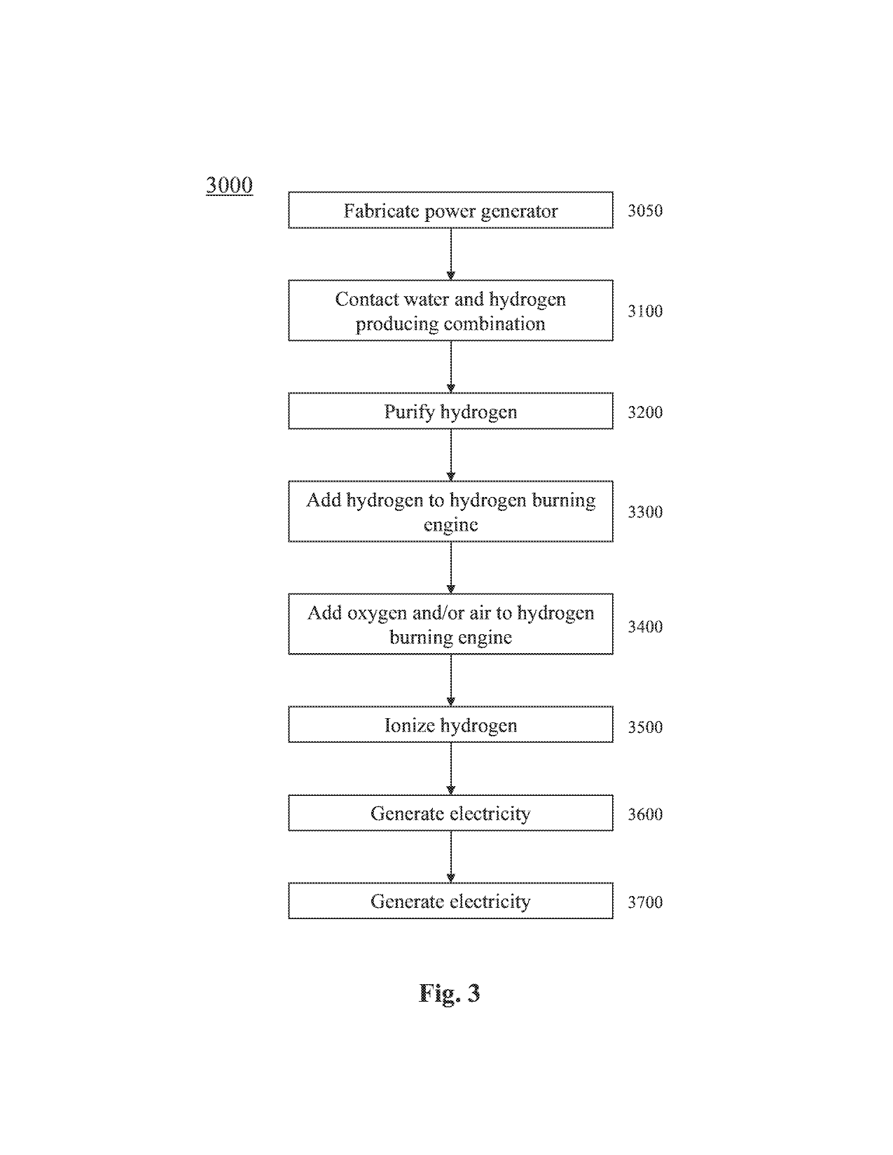

FIG. 3 is a flowchart of an exemplary embodiment of a method 3000. At activity 3050, a power generator can be fabricated. The power generator can be adapted to produce electricity from water. The power generator can comprise a hydrogen generation system, hydrogen fuel cell subsystem, output voltage regulator, capacitor, an inverter, hydrogen burning engine, and/or other parts adapted to convert chemical energy comprised by hydrogen produced from water via the hydrogen generation system into electrical energy, etc. The hydrogen fuel cell subsystem can comprise at least one of a fuel cell and a hydrogen internal combustion engine. The hydrogen generation system can be adapted to receive water molecules from a water supply source. The hydrogen generation system can comprise a hydrogen producing combination, hydrogen collector, hydrogen purifier, hydrogen outlet, and/or a hydrogen storage device, etc. The hydrogen producing combination can be adapted to generate hydrogen used by the hydrogen burning engine. The hydrogen producing combination can comprise one or more electron donating molecules, reduction molecules, and/or a catalyst, etc. The hydrogen producing combination can be comprised by a replaceable cartridge. The replaceable cartridge can comprise a porous media adapted for contacting water molecules with the hydrogen producing combination.

The hydrogen generation subsystem can comprise a replaceable container, which can comprise at least one of glass, plastic, metal, ceramic, wood, and composite materials. The replaceable container can comprise a substantially closed box having a water supply inlet and a produced hydrogen outlet. The replaceable container 5100 can comprise a hydrogen producing combination, which can comprise at least one of:
a plurality of chemicals;
periodic table first column metals;
periodic table III-V group elements;
alkaline materials;
reduction molecules;
hydrides, the hydrides comprising at least one of ionic hydrides, covalent hydrides, interstitial hydrides, metal hydrides, and/or deuterides; etc.

The hydrogen generation subsystem can be adapted to receive water molecules from a water supply source. The hydrogen generation subsystem can comprise a water supply control valve, a water pathway, a lid, a container, a water level controlling container, a hydrogen producing combination container, and/or a net open to hydrogen producing combination, etc. The hydrogen generation subsystem can be adapted to generate hydrogen used by the hydrogen fuel cell subsystem. The hydrogen producing combination can comprise one or more specific electron donating molecules selected from reduction molecules, alkaline metals, alkaline molecules, and/or catalyst, etc.

The hydrogen burning engine can comprise a hydrogen pathway, an oxygen/air pathway, and a proton exchange membrane (PEM) intercalated between catalyst layers deposited on a porous conductive substrate. The PEM can comprise at least one of alkyl sulfonate, sulfonated nano carbon, and sulfonated carbon black encapsulated in a first polymer, wherein a weight ratio of (sulfonated molecule/polymer) varies between 0.0001 to 10, sulfonated polymers, and sulfonated compound embedded in a polymer matrix, said polymer matrix comprising one or more embedded substances comprising silanol—SiOH derivatives, —SiO derivatives themselves, silanol, or—SiO derivatives. The PEM can comprise silicon, silanol, —SiOH, —SiH, silane, sulfonated nano carbon materials encapsulated in a first polymer forming a membrane, sulfonated polymers, and/or sulfonated compound embedded in a polymer matrix, etc. In certain exemplary embodiments, the first polymer can comprise an emulsion polymer. The hydrogen pathway and/or the oxygen/air pathway can comprise a conductive frame, which can comprise at least one of a metal, metal alloy, graphite, graphene, and hybrid graphene composite, and/or carbon/metal alloy, etc. The hydrogen pathway and/or the oxygen/air pathway can comprise a conductive frame and a porous conductive substrate. In certain exemplary embodiments, the hydrogen pathway can comprise cotton packed on a surface of the porous conductive substrate. The frame can be made conductive via a coating of a solid state material having at least one of a first zero band gap material and an electrical conductive material. The first zero band gap material can comprise at least one of a metal, metal alloy, graphene, hybrid graphene composite, carbon nano tube, carbon nano horn, carbon nano wire, carbon nano rod, and/or silicon nano wire, etc. The electrical conductive material can comprise at least one of a tubular nano carbon including carbon nano tube, carbon nano wire, carbon nano rod, carbon nanohorn, and/or carbon black, etc.

The hydrogen pathway and/or the oxygen/air pathway can comprise an insulating plastic frame or other frame coated with a conductive coating comprising a solid state material having at least one of a first zero band gap material and an electrically conductive material. The first zero band gap material can comprise at least one of a metal, metal alloy, graphene, graphene oxide, hybrid graphene composite, carbon nano tube, carbon nano horn, carbon nano wire, carbon nano rod, silicon nano wire. The electrical conductive material can comprise at least one of a tubular nano carbon including carbon nano tube, carbon nano wire, carbon nano rod, carbon nano horn, and/or carbon black, etc.

The fuel cell can comprise a catalyst, which can comprise a composite. The composite can comprise at least one of a second zero band gap material, conductive nano carbon material, conductive oxide material, semiconductor, and/or conductive carbon, etc. The catalyst can have work function equal or greater than approximately 6.35 electron volts.

At activity 3100, water can be contacted with a hydrogen producing combination in the hydrogen generation system. The water can be provided by a water supply source, which can supply gas and/or liquid phase water to the hydrogen generation system. The hydrogen producing combination can be a catalyst adapted to facilitate the reduction of water to hydrogen. The hydrogen producing combination can comprise electron donating molecules such as Li, Be, Na, K, Mg, Al, Mn, Zn, Pb, Sn, Cu, Ca, Ba, Zn, Cr, S, Fe, Co, Ni, and/or Cu, etc. These molecules can be used in the form of nano materials in which the hydrogen producing combination can comprise additives, such as amines. The amines can comprise, for example, pyridine, morpholine, aminobenzoic acid, amino sulfonic acid, and/or tetra methyl ammonium hydroxide (“TMAH”), etc. The hydrogen producing combination can comprise additives, such as liquid glass; a sodium silica gel such as K₂Na, Na₂SiO₃, and/or Na₂Si₂O₅, etc.; sodium silicides such as NaSi, Na₂Si, alumina, and/or SiO₂, etc.; and/or glass product of glass and alkaline, etc. The hydrogen producing combination can comprise additives such as reduction molecules NaBH₄, (A1Cl₃/NaBH₄), LiAlH₄, oxalic acid, NaH, CaH₂, and/or H₂O₂, etc.

The hydrogen producing combination can comprise at least one element capable of donating electron with and without additives and/or a reduction agent. The at least one element can comprise an organic acid, silica, liquid glass, or glass product generated by the reaction of the at least one element with glass. The hydrogen producing combination can be placed and/or embedded in and/or on a substance adapted to enhance contact of the hydrogen producing combination with water. The hydrogen producing combination can be nanoencapsulated in a nano container such as SWNT, DWNT, MWNT, SPNT, or can be microencapsulated in a micro container with the size ranging from several hundred microns to a few millimeters. The micro container can be a microcapsule or molecular sieve. The hydrogen producing combination can be stored in the micro or nano container in the solid form and can be delivered to contact and react with a water molecule to form hydrogen. The hydrogen producing combination can be microencapsulated in a polymer adapted to facilitate contact between water molecules and electron donating molecules. In certain exemplary embodiments, the hydrogen producing combination can be stored in a cartridge, which can be adapted to be nondestructively replaced in the system. In certain exemplary embodiments, the hydrogen producing combination is microencapsulated in a second polymer adapted for contacting water molecules with the hydrogen producing combination. The hydrogen producing combination can comprise a reducing agent, which can comprise boron. In certain exemplary embodiments, the replaceable cartridge can be a filtering tea bag or a framing net close box.

The hydrogen producing combination can comprise bacteria producing bio-hydrogen under certain conditions, such as fermented paddy husk and/or naturally fermented garbage, etc.

At activity 3200, produced hydrogen can be purified. The purification of the hydrogen can involve removal of substantially all water, catalyst, and/or oxygen from the hydrogen. Purifying the hydrogen can improve the performance and/or service life of a fuel cell in which the hydrogen is used.

At activity 3300, the purified hydrogen can be added to the hydrogen burning engine. For example, the hydrogen can flow to a catalyst layer at which the hydrogen can be ionized into an electron and a proton H+. The electron releases energy in the form of electrical energy. The hydrogen can flow to the catalyst layer via a substrate adapted to be relatively porous with respect to hydrogen. The hydrogen can enter the substrate via a conductive frame that defines a set of gaps. In certain exemplary embodiments, the conductive frame can be covered by thin film of metal prepared by vacuum sublimation in conjunction with the porous conductive substrate. In certain exemplary embodiments, the conductive frame can be covered by a thin film of metal prepared by electroplating in conjunction with the porous conductive substrate.

At activity 3400, oxygen and/or air can be added to the hydrogen burning engine. The hydrogen burning engine can comprise a PEM, which can be intercalated between an opposing pair of catalyst layers. Each of the opposing pair of catalyst layers can be deposited on a porous conductive substrate. In certain exemplary embodiments, one or more components of the hydrogen burning engine can comprise a hybrid graphene composite produced according to a method disclosed in related U.S. patent application Ser. No. 13/290,108. For example, the conductive frame, the conductive substrate, the catalyst layer, and/or the PEM can comprise the hybrid graphene composite. The hydrogen burning engine can comprise an air transport pathway and/or an oxygen transport pathway.

At activity 3500, hydrogen gas which enters the anodic catalyst is ionized into a proton H+ traveling through the PEM and electron producing electricity to the power generator. At the cathodic catalyst, the proton H+ reacts with electron and oxygen O2 in the air, forming a water molecule. This activity provides cleaned water at the cathode no matter what kinds of water which had been used in the anode. Thus, the watered power generator can work as a water purifier as it produces relatively pure water.

At activity 3600, electricity can be generated responsive to the reaction of hydrogen and oxygen in the hydrogen burning engine. The electricity generated can be routed through an inverter adapted to convert DC signals into AC signals.

At activity 3700, electricity generated via the hydrogen burning engine can be used. For example, the electricity produced by the hydrogen burning engine can be utilized to power a household, computer system, computing device, locomotive, blower, crusher, grinder, saw, heater, air conditioner, canner, distilling device, bicycle, motorcycle, automobile, industrial power plant, airplane, conveyor, pump, valve actuator, battery, portable devices, street lighting tool, power plant, transportation vehicle, industrial power plant, space shuttle, flying car, wood grinder, lawn mower, grass cutter, chain saw, a device or tools utilized for outdoor and indoor works, water purifier, and/or electrical energy distribution grid, etc.

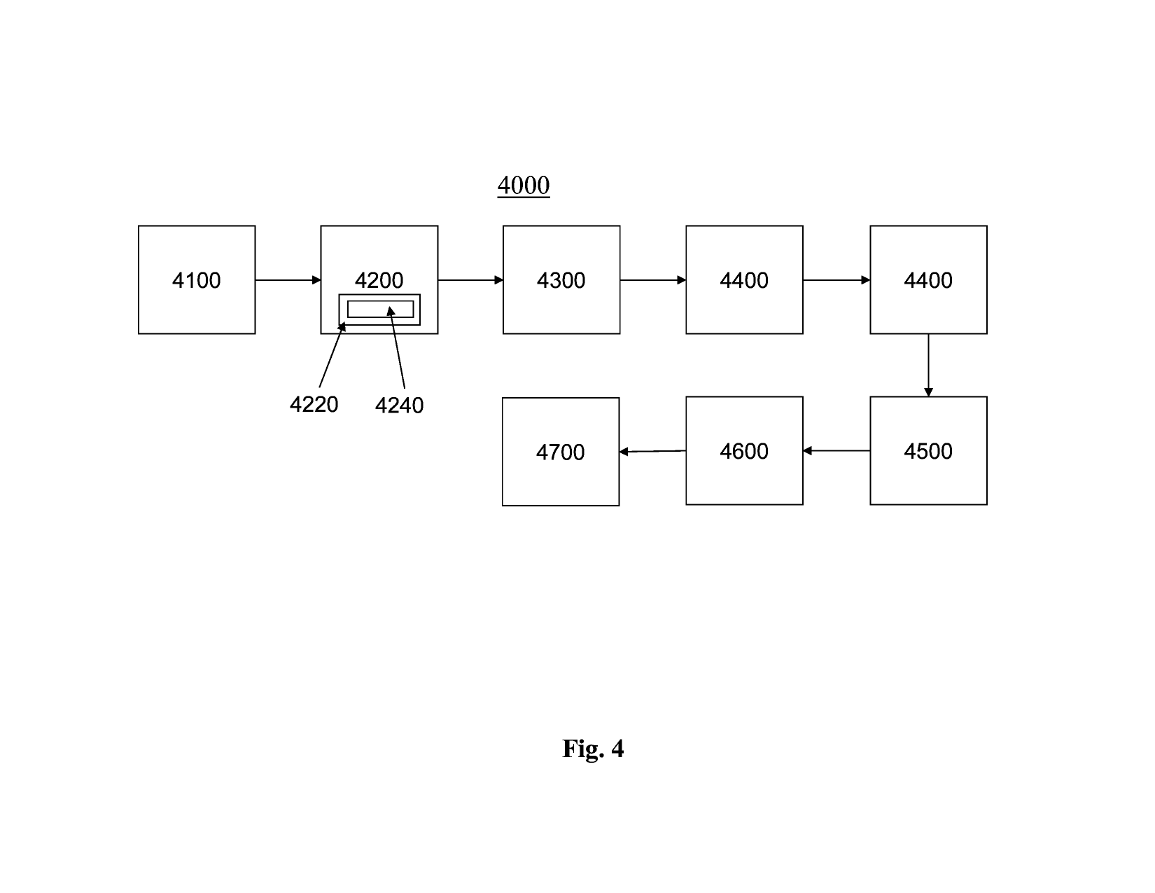

FIG. 4 is a block diagram of an exemplary embodiment of a power generator 4000, which can comprise a hydrogen generation system 4100, hydrogen burning engine 4200, catalyst 4220, composite 4240, output voltage regulator 4300, capacitor 4400, inverter 4500, other parts adapted to convert chemical energy comprised by hydrogen produced from water via the hydrogen generation system into electrical energy 4600, and/or electrical load 4700.

Hydrogen generation system 4100 can be adapted to generate hydrogen used by hydrogen burning engine 4200. Hydrogen burning engine 4200 can comprise catalyst 4220, which can comprise composite 4240. Composite 4240 can comprise at least one of a second zero band gap material, conductive nano carbon material, conductive oxide material, semiconductor, and/or conductive carbon, etc. Catalyst 4220 can have a work function greater than approximately 6.35 electron volts. Catalyst 4220 can be a composite of zero band gap materials with nano carbon material such as carbon black, carbon nano tube, carbon nano horn, graphene, graphite, graphene hybrid composite, carbon nano wire, and/or an alloy of zero band gap material and nano carbon, etc.

In certain exemplary embodiments, load 4700 can be one or more of portable devices, street lighting tool, a household, bicycle, motorcycle, automobile, power plant, airplane, space shuttle, and/or flying car, etc. Load 4700 can be adapted to use electricity generated via hydrogen burning engine 4200.

### DEFINITIONS

When the following terms are used substantively herein, the accompanying definitions apply. These terms and definitions are presented consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.
a —at least one.
activity—an action, act, step, and/or process or portion thereof.
adapted to—made suitable or fit for a specific use or situation.
adsorb—to adhere to a surface.
airplane—a powered flying vehicle with fixed wings and a weight greater than that of the air it displaces.
and/or—either in conjunction with or in alternative to.
apparatus—an appliance or device for a particular purpose.
automobile—a road vehicle that uses some form of energy to convey people.
bicycle—a vehicle composed of two wheels held in a frame one behind the other with handlebars attached to the front wheel.
blend—to mix together.
can—is capable of, in at least some embodiments.
carbon nanofiber—a substantially cylindrical nanostructure with graphene layers arranged as stacked cones, cups, or plates.
carbon nanorod—a nanocrystalline form of diamond.
carbon nanotube—a carbon nanofiber comprising graphene layers wrapped into substantially perfect cylinders.
carbon nanowires—a nanostructure comprising carbon and having a diameter of approximately a nanometer (10⁻⁹ meters) and in which electrons are quantum confined laterally.
catalyst—a substance adapted to enhance chemical reaction kinetics.
ceramic—an inorganic, nonmetallic solid.
composite—a material comprising at least two constituents at the nanometer or molecular level.
comprising—including but not limited to.
conduct—to transmit electrical energy.
conductive—adapted to transmit electrical energy.
conductive frame—a supporting structure that is adapted to conduct electrical energy.
porous conductive substrate—a metal mesh.
contact—to physically touch.
cotton—a soft white fibrous substance that surrounds the seeds of a tropical or subtropical cotton plant.
couple—to join, connect, fasten, link, and/or associate together.
device—a machine, manufacture, and/or collection thereof.
dispersion film—the thin layer made by vacuum sublimation process or coating deposited on a substrate from a solution.
electrical conductor—a substance adapted to transmit electrical energy.
electricity—a form of energy resulting from the existence of charged particles (such as electrons or protons), either statically as an accumulation of charge or dynamically as a current.
electrocatalyst—a material adapted to increase the rate of a chemical reaction at an electrode surface without being consumed by the chemical reaction.
electromagnetic shielding—a barrier, made of conductive and/or magnetic materials, adapted to reduce an electromagnetic field in a space by blocking the field.
electron donating molecules—a chemical entity that donates electrons to another compound; a reducing agent that, by virtue of donating electrons, is itself oxidized in the process.
electroplate—to coat via electrolytic deposition with a metal.
emulsion polymer—a polymer that exists in two phases; a continuous phase (such as water) and a dispersed phase that comprises polymer particles. The dispersed phase can be suspended in the continuous phase through the use of substances called emulsifiers.
encapsulate—to substantially enclose with a protective coating and/or membrane.
fabricate—to construct.
flake—a substantially planar lattice of carbon atoms.
flying car—an aircraft that can also travel on roads.
framing net close box—a container that is not fully opened that has a porous frame adapted to allow the delivery of a hydrogen producing combination to water.
fuel cell—a system adapted to convert chemical energy from a fuel into electricity through a chemical reaction with oxygen or another oxidizing agent.
transport pathway—a set of interconnected defined openings adapted to allow the passage of a gas such as hydrogen and/or oxygen via a predetermined route in a hydrogen burning engine.
generate—to produce.
graphene—an allotrope of carbon having a structure of approximately one-atom-thick planar sheets of sp2-bonded carbon atoms in a honeycomb crystal lattice.
household—a house and its occupants as a unit.
hybrid composite—a material comprising two constituents at the nanometer or molecular level.
hybrid graphene composite—a material comprising graphene and at least one other constituent that have been combined at the nanometer or molecular level.
hydrogen burning engine—a system adapted to convert chemical energy stored in hydrogen to electrical energy.
hydrogen collector—a device and/or system adapted to gather together generated hydrogen.
hydrogen generation system—a system adapted to produce hydrogen from water.
hydrogen outlet—an aperture of a device and/or system adapted to convey hydrogen.
hydrogen producing combination—a system adapted to produce hydrogen from water.
hydrogen purifier—a device and/or system adapted to remove one or more impurities from hydrogen produced from water.
hydrogen storage device—a device adapted to act as a repository for hydrogen.
ink—a liquid or paste that contains pigments and/or dyes adapted to produce electrically conductive patterns when used in a suitable system.
inverter—a device and/or system adapted to convert direct current into alternating current.
iron relative—a compound comprising at least one of iron inorganic salts, iron organic salts, iron chelates, iron organo metallic compounds.
lacquer—a varnish that dries by solvent evaporation and/or a curing process to produce a relatively durable finish.
may—is allowed and/or permitted to, in at least some embodiments.
method—a process, procedure, and/or collection of related activities for accomplishing something.
motorcycle—a two-wheeled vehicle that is powered by a motor.
nano carbon—carbon materials having average particle size less than approximately 100 nanometers in size, carbon-based materials that can be bonded at the molecular level in differing ways to achieve unique properties, which comprise nanotubes, buckytubes, and/or fullerenes, etc.
nano rod—a nanocrystalline form of carbon having rod shape in nano scale (less than 100 nm).
nano wire—a nanostructure having a diameter of less than 100 nm and length less than approximately 100 nanometers. Si nano wire, carbon nano wire, ZnO nano rod are examples of nano wire and in which electrons are quantum confined laterally.
nano-platelets—nanoparticles comprising stacks of graphene that are 1 to 15 nanometers thick, with diameters ranging from sub-micrometer to 100 micrometers.
obtain—to come into possession of, get, acquire, and/or procure.
operatively—in a manner adapted to achieve an effective and/or desired result.
oven—a chamber used adapted for heating a substance.
oxide—a chemical compound that contains at least one oxygen atom in its chemical formula.
plastic frame—a substantially rigid structure that comprises synthetic or semisynthetic organic carbon-based materials that can be molded or extruded into objects, films, filaments, and/or used for making coatings and/or adhesives, etc.
polymer—a macromolecule comprising repeating structural subunits that are typically connected by covalent chemical bonds.
porous—having spaces or holes through which a liquid and/or a gas may pass.
power generator—a system adapted to produce electrical energy.
present—being in a specified thing.
produce—to make or manufacture.
proton exchange membrane—a semi-permeable membrane that acts as an electrolyte (which is proton conducting) as well as a barrier film, impermeable to gases such as oxygen or hydrogen, separating the hydrogen-rich feed in the cathode compartment of a fuel cell from the oxygen-rich anode.
provide—to furnish, supply, give, and/or make available.
pyrolyze—to thermochemically decompose an organic material at a temperature above approximately 200 degrees Celsius in the substantial absence of oxygen.
reducing agent—an element or compound in a reduction-oxidation (redox) reaction that donates an electron.
reduction agent—a substance comprising one or more of NaOH, KOH, NaBH₄, (AlCl₃—NaBH₄), NaK₂, NaSi, Na₂Si, and Na₄Si₄.
replaceable cartridge—a container that is adapted to be substantially nondestructively installed and removed from an operative installation.
salt—any of a class of compounds formed by the replacement of one or more hydrogen atoms of an acid with elements or groups, which are composed of anions and cations.
semi-conducting—having a conductivity roughly in the range of 10³ to 10⁻⁸ siemens per centimeter.
semiconductor—a substance, such as silicon or germanium, with electrical conductivity intermediate between that of an insulator and a conductor.
solar cell—a solid state electrical device adapted to convert light energy directly into electricity via the photovoltaic effect.
solid carbon source—an organic substance that is in a physical state in which it resists changes in size and shape.
solid state material—a substantially solid phase substance comprising, particularly, but not necessarily exclusively, non-molecular solids.
solvent—a substance adapted to dissolves another solid, liquid, or gaseous solute.
specific catalyst—a predetermined substance adapted to enhance a chemical reaction rate.
storage device—a device adapted to act as a repository for electrical energy.
store—to accumulate or retain for future use.
substantially—to a great extent or degree.
substrate—a supporting material on which a circuit is formed or fabricated.
surface—an outside layer of something.
system—a collection of mechanisms, devices, machines, articles of manufacture, processes, data, and/or instructions, the collection designed to perform one or more specific functions.
tubular—having a substantially cylindrical shape.
turbo engine—a motor comprising a gas compressor that is used for forced induction.
unoxidizing environment—an atmosphere substantially devoid of reactive oxygen.
vacuum sublimation—a process in which a solid substance undergoes a phase change to a gas due to a partial removal of air from the surface of the solid substance.
via—by way of and/or utilizing.
voltage regulator—a device adapted to control an electrical voltage in a circuit.
water supply source—a system adapted to provide H₂O to a fuel cell and/or hydrogen generator.
zero band gap material—a substance in which substantially no threshold energy is required to move electrons from occupied states in the valence band to empty states in the conduction band. As a consequence, such materials have unique properties including an extreme sensitivity of the band structure to external influences such as pressure or and/or magnetic field. The electron mobility of a zero band gap material is 2-4 orders of magnitude higher than that for classical semiconductors.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.
Thus, regardless of the content of any portion (e.g., title, field, background, summary, description, abstract, drawing figure, etc.) of this application, unless clearly specified to the contrary, such as via explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing figure, etc.) of this application, other than the claims themselves, is to be regarded as illustrative in nature, and not as restrictive, and the scope of subject matter protected by any patent that issues based on this application is defined only by the claims of that patent.

What is claimed is:

1. A method comprising a plurality of activities, comprising:
fabricating a power generator, said power generator adapted to produce electricity from water, said power generator comprising a hydrogen generation subsystem, hydrogen fuel cell subsystem, output voltage regulator, capacitor, inverter, and other parts adapted to convert chemical energy comprised by hydrogen produced from water via said hydrogen generation subsystem into electrical energy, said hydrogen fuel cell subsystem comprising at least one of a fuel cell and a hydrogen internal combustion engine;
said hydrogen generation subsystem comprising a replaceable container, said replaceable container comprising at least one of glass, plastic, metal, ceramic, wood, and composite materials, replaceable container a substantially closed box having a water supply inlet and produced hydrogen outlet, replaceable container comprising a hydrogen producing combination, said hydrogen producing combination microencapsulated in a micro container, or nanoencapsulated or nanoencapsulated in a nano container, said hydrogen producing combination stored in a secondary container that is relatively porous to liquid water and substantially completely enclosed, said hydrogen producing combination comprising at least one of:
a plurality of chemicals;
periodic table first column metals;
nano materials comprising one or more periodic table III-V group elements;
alkaline materials; and
reduction molecules;
hydrides, said hydrides comprising at least one of ionic hydrides, covalent hydrides, interstitial hydrides, metal hydrides, and/or deuterides;
said hydrogen producing combination comprising a reduction agent;
said hydrogen generation subsystem adapted to receive water molecules from a water supply source, said hydrogen generation subsystem comprising a water supply control valve, a water pathway, a lid, a container, a water level controlling container, a hydrogen producing combination container, and a net open to hydrogen producing combination, said hydrogen generation subsystem adapted to generate hydrogen used by said hydrogen fuel cell subsystem; said hydrogen producing combination comprising one or more specific electron donating molecules selected from reduction molecules, alkaline metals, alkaline molecules, and catalyst;
said hydrogen fuel cell system comprising a hydrogen pathway, an oxygen/air pathway, and a proton exchange membrane (“PEM”) intercalated between a first catalyst layer and a second catalyst layer, said PEM deposited on a porous conductive substrate, said PEM comprising at least one of alkyl sulfonate, sulfonated nano carbon, and sulfonated carbon black encapsulated in a first polymer, wherein a weight ratio of (sulfonated molecule/polymer) varies between 0.0001 to 10, sulfonated polymers, and sulfonated compound embedded in a polymer matrix, said polymer matrix comprising one or more embedded substances comprising silanol—SiOH derivatives, —SiO derivatives themselves, silanol, and —SiO derivatives;
said hydrogen pathway and said oxygen/air pathway comprising at least one of:
a conductive frame comprising at least one of a metal, metal alloy, graphite, graphene, graphene oxide, hybrid graphene composite, and carbon/metal alloy, said hydrogen pathway and said oxygen/air pathway comprising said porous conductive substrate; and
an insulating plastic frame or other frame coated with a conductive coating comprising a solid state material having at least one of a first zero band gap material and an electrically conductive material; wherein said first zero band gap material comprises at least one of a metal, metal alloy, graphene, graphene oxide, hybrid graphene composite, carbon nano tube, carbon nano horn, carbon nano wire, carbon nano rod, silicon nano wire, or wherein said electrical conductive material comprises at least one of a tubular nano carbon including carbon nano tube, carbon nano wire, carbon nano rod, carbon nano horn, and carbon black; and
when said hydrogen fuel cell subsystem is said fuel cell, said fuel cell comprises said first catalyst layer and said second catalyst layer, said first catalyst and said second catalyst comprising a composite, said composite comprising at least one of a second zero band gap material, conductive nano carbon material, conductive oxide material, carbon black and nano carbon, semiconductor, and conductive carbon, at least one of said first catalyst and said second catalyst having a work function greater than 6.35 electron volts.

2. The method of claim 1, further comprising:
using electricity generated via water to provide electrical energy to an electrical load 4700 comprising at least one of portable devices, street lighting tool, a household, power plant, transportation vehicles, bicycle, motorcycle, automobile, industrial power plant, airplane, space shuttle, flying car, wood grinder, lawn mower, chain saw, a device or tools utilized for outdoor and indoor works, and water purifier.

3. The method of claim 1, further comprising:
using hydrogen gas generated from water via said hydrogen internal combustion engine to provide electrical energy to at least one of at least one load 4700 comprising a portable device, street lighting tool, a household power plant, transportation vehicle, bicycle, motorcycle, automobile, industrial power plant, airplane, space shuttle, flying car, wood grinder, grass cutter, chain saw, any device or tool utilized for outdoor and indoor works, and water purifier.

4. The method of claim 1, wherein:
said inverter is adapted to convert DC signals into AC signals.

5. The method of claim 1, wherein:
said water supply source supplies gas phase water to said hydrogen generation subsystem.

6. The method of claim 1, wherein:
said hydrogen producing combination comprises at least one element capable of donating electron with and without additives, said at least one element comprising an organic acid, silica, liquid glass, or glass product generated by a reaction of said at least one element with glass.

7. The method of claim 1, wherein:
said hydrogen producing combination is nanoencapsulated or microencapsulated in a carbon nano tube, microcapsule, or molecular sieve; and
said hydrogen producing combination is microencapsulated in a second polymer adapted for contacting water molecules with said hydrogen producing combination.

8. The method of claim 1, wherein:
said first polymer is an emulsion polymer.

9. The method of claim 1, wherein:
said PEM comprises silicon.

10. The method of claim 1, wherein:
said PEM comprises at least one of silanol, —SiOH, —SiH, —SiO, and silane coupling agent.

11. The method of claim 1, wherein:
said hydrogen fuel cell system comprises an air transport pathway.

12. The method of claim 1, wherein:
said hydrogen fuel cell system comprises an oxygen transport pathway.

13. The method of claim 1, wherein:
said conductive frame is covered by thin film of metal prepared by vacuum sublimation in conjunction with said porous conductive substrate.

14. The method of claim 1, wherein:
said conductive frame is covered by a thin film of metal prepared by electroplating in conjunction with said porous conductive substrate.

15. The method of claim 1, wherein:
said hydrogen pathway comprises cotton packed on a surface of said porous conductive substrate.

16. A method comprising a plurality of activities, comprising:
fabricating a power generator, said power generator adapted to produce electricity from water, said power generator comprising a hydrogen generation subsystem, hydrogen fuel cell subsystem, output voltage regulator, capacitor, inverter, and other parts adapted to convert chemical energy comprised by hydrogen produced from water via said hydrogen generation subsystem into electrical energy, said hydrogen fuel cell subsystem comprising at least one of a fuel cell and a hydrogen internal combustion engine;
said hydrogen generation subsystem adapted to receive water molecules from a water supply source, said hydrogen generation subsystem comprising a hydrogen producing combination, hydrogen collector, hydrogen cooler, hydrogen purifier, hydrogen outlet, and a hydrogen storage device, said hydrogen producing combination adapted to generate hydrogen used by said hydrogen fuel cell subsystem; said hydrogen producing combination comprising one or more specific electron donating molecules selected from reduction molecules, alkaline metals, alkaline molecules, catalyst, said hydrogen producing combination comprised by a replaceable cartridge, said replaceable cartridge comprising a porous media adapted for contacting water molecules with said hydrogen producing combination;
said hydrogen fuel cell subsystem comprising a hydrogen pathway, an oxygen/air pathway, and a proton exchange membrane (PEM) intercalated between a first catalyst layer and a second catalyst layer, said PEM deposited on a porous conductive substrate, said PEM comprising sulfonated nano carbon and sulfonated carbon black encapsulated in a first polymer forming a membrane, sulfonated polymers, and sulfonated compound embedded in a polymer matrix, said polymer matrix comprising one or more embedded substances comprising silanol —SiOH derivatives, —SiO derivatives themselves, silanol, or —SiO derivatives;
said hydrogen pathway and said oxygen/air pathway comprising at least one of:
a conductive frame comprising at least one of a metal, metal alloy, graphite, graphene, graphene oxide, hybrid graphene composite, and carbon/metal alloy, said hydrogen pathway and said oxygen/air pathway comprising said porous conductive substrate; and
an insulating plastic frame or other frame coated with a conductive coating comprising a solid state material having at least one of a first zero band gap material and an electrically conductive material; wherein said first zero band gap material comprises at least one of a metal, metal alloy, graphene, graphene oxide, hybrid graphene composite, carbon nano tube, carbon nano horn, carbon nano wire, carbon nano rod, silicon nano wire, or wherein said electrical conductive material comprises at least one of a tubular nano carbon including carbon nano tube, carbon nano wire, carbon nano rod, carbon nano horn, and carbon black; and
when said hydrogen fuel cell subsystem is said fuel cell, said fuel cell comprises said first catalyst layer and said second catalyst layer, said first catalyst layer and said second catalyst layer comprising a composite, said composite comprising at least one of a second zero band gap material, conductive nano carbon material, conductive oxide material, carbon black and nano carbon, semiconductor, and conductive carbon, at least one of said first catalyst layer and said second catalyst layer having work function greater than 6.35 electron volts.

17. A system comprising:
a water supply source, hydrogen generation subsystem, hydrogen producing combination, hydrogen collector, hydrogen purifier, hydrogen outlet, fuel cell or a hydrogen internal combustion engine, and a storage device, wherein;
said hydrogen generation subsystem adapted to generate hydrogen used by said fuel cell or said hydrogen internal combustion engine from a water molecule; said hydrogen producing combination comprising one or more electron donating molecules, said hydrogen producing combination comprised by a replaceable cartridge, said replaceable cartridge comprising a porous media adapted for contacting water molecules with said hydrogen producing combination;
said hydrogen generation subsystem comprising a port adapted to receive water as well as a hydrogen outlet;
said fuel cell comprising a hydrogen pathway and a proton exchange membrane (PEM) intercalated between catalyst layers deposited on a porous conductive substrate, said PEM comprising sulfonated nano carbon encapsulated in a first polymer forming a membrane;
said hydrogen pathway comprising a conductive frame, said conductive frame comprising at least one of a metal, graphite, graphene, and hybrid graphene composite, said hydrogen pathway comprising a conductive frame and a porous conductive substrate; and
said storage device adapted to store hydrogen produced via said hydrogen producing combination.

18. The system of claim 17, wherein:
said replaceable cartridge is a filtering tea bag or a framing net close box.
